(19) United States
(12) Patent Application Publication
(10) Pub. No.: US 2023/0014449 A1
(43) Pub. Date: Jan. 19, 2023

(54) LIQUID-COOLING HEAT DISSIPATION DEVICE AND LIQUID-COOLING HEAT DISSIPATION SYSTEM

(71) Applicant: Huizhou Hanxu Hardware Plastic Technology Co., Ltd., Huizhou City (CN)

(72) Inventor: Tsung-Hsien Huang, Huizhou City (CN)

(21) Appl. No.: 17/547,250

(22) Filed: Dec. 10, 2021

(30) Foreign Application Priority Data
Jul. 13, 2021 (CN) 202110791257.3

(51) Int. Cl. F28D 15/04; F28D 15/02

(52) U.S. Cl. CPC F28D 15/046; F28D 15/0233

(57) ABSTRACT

A liquid-cooling heat dissipation device and a liquid-cooling heat dissipation system for improving heat transfer efficiency are disclosed. The liquid-cooling heat dissipation device includes a vapor chamber, a liquid-separating cover, and a housing. The housing has a cold liquid inlet and a hot liquid outlet. An accommodating cavity is formed between the vapor chamber and the housing. By providing the vapor chamber, the heat transfer efficiency of the liquid-cooling heat dissipation device is improved greatly to realize rapid heat dissipation.

### BACKGROUND OF THE INVENTION

### 1. Field of the Invention

The present invention relates to a liquid-cooling heat dissipation device, and more particularly to a liquid-cooling heat dissipation device and a liquid-cooling heat dissipation system for improving heat transfer efficiency.

### 2. Description of the Prior Art

A conventional liquid-cooling heat dissipation device usually includes a heat dissipation base, an inner cover, an impeller, a lower housing, and a motor. The heat dissipation base absorbs the heat of a heat-generating component, and the cold liquid flowing into the liquid-cooling block absorbs the heat from the heat dissipation base to become hot liquid. The hot liquid is discharged from the liquid-cooling block to dissipate heat and becomes cold liquid to flow back to the liquid-cooling block to circulate and absorb heat. In actual use, for products that need rapid heat dissipation, the heat dissipation efficiency cannot meet the needs of use. As a result, the heat dissipation effect is not good.

Accordingly, the inventor of the present invention has devoted himself based on his many years of practical experiences to solve these problems.

### SUMMARY OF THE INVENTION

In view of the deficiencies in the prior art, the primary object of the present invention is to provide a liquid-cooling heat dissipation device and a liquid-cooling heat dissipation system for improving heat transfer efficiency. By providing a vapor chamber, the heat transfer efficiency of the liquid-cooling heat dissipation device is improved greatly to realize rapid heat dissipation.

In order to achieve the above object, the present invention adopts the following solutions.

A liquid-cooling heat dissipation device comprises a vapor chamber, a liquid-separating cover, and a housing.

The housing has a cold liquid inlet and a hot liquid outlet. An accommodating cavity is formed between the vapor chamber and the housing. The liquid-separating cover covers the vapor chamber to separate the accommodating cavity into a cold liquid cavity and a hot liquid cavity. The cold liquid inlet and the hot liquid outlet communicate with the cold liquid cavity and the hot liquid cavity, respectively. A top of the liquid-separating cover is formed with a first perforation communicating with the cold liquid cavity and an interior of the liquid-separating cover. A bottom of a peripheral side of the liquid-separating cover is formed with a second perforation communicating with the hot liquid cavity and the interior of the liquid-separating cover.

A cold liquid flows through the cold liquid inlet into the cold liquid cavity and then flows through the first perforation into the exterior of the liquid-separating cover. The cold liquid absorbs heat of the vapor chamber to become hot liquid. The hot liquid flows through the second perforation into the hot liquid cavity and then flows out of the housing via the hot liquid outlet.

A liquid-cooling heat dissipation system comprises a liquid-cooling radiator, a cold liquid input pipe and a hot liquid output pipe that are connected to the liquid-cooling radiator, and the foregoing liquid-cooling heat dissipation device. The cold liquid input pipe is connected to the cold liquid inlet. The hot liquid output pipe is connected to the hot liquid outlet.

The cold liquid in the cold liquid input pipe flows into the housing through the cold liquid inlet and absorbs heat of the vapor chamber to become hot liquid. The hot liquid flows out of the housing via the hot liquid outlet and flows to the liquid-cooling radiator through the hot liquid output pipe. The liquid-cooling radiator dissipates heat of the hot liquid to become cold liquid. The cold liquid flows into the cold liquid input pipe again to be circulated. The liquid pump is configured to supply circulation power.

Compared with the prior art, the present invention has obvious advantages and beneficial effects. Specifically, it can be known from the above technical solutions. By providing the vapor chamber, the heat transfer efficiency of the liquid-cooling heat dissipation device is improved greatly to realize rapid heat dissipation, meeting the heat dissipation requirements of products, especially for products that need rapid heat dissipation to ensure ideal heat dissipation effects.

In addition, the structural design of the vapor chamber, the liquid-separating cover and the housing is ingenious and reasonable, in cooperation with the liquid flow direction of the liquid inlet, heat transfer and the liquid outlet. The hot liquid is discharged from the periphery of the liquid-separating cover to ensure that the cold liquid is in full contact with the surface of the protruding portion of the vapor chamber to transfer heat fast.

### BRIEF DESCRIPTION OF THE DRAWINGS

FIG. 1 is a perspective view of the liquid-cooling heat dissipation device according to a first embodiment of the present invention;

FIG. 2 is a top view of the liquid-cooling heat dissipation device according to the first embodiment of the present invention;

FIG. 3 is an exploded of the liquid-cooling heat dissipation device according to the first embodiment of the present invention;

FIG. 4 is a cross-sectional view taken along line A-A of FIG. 2, showing the direction of the liquid flow;

FIG. 5 is a cross-sectional view of the liquid-separating cover and the vapor chamber according to the first embodiment of the present invention;

FIG. 6 is a top view of the liquid-separating cover and the vapor chamber according to the first embodiment of the present invention;

FIG. 7 is a perspective view of another structure of the liquid-separating cover according to the first embodiment of the present invention;

FIG. 8 is a perspective view of the housing according to the first embodiment of the present invention;

FIG. 9 is a perspective view of the liquid-cooling heat dissipation device of the first embodiment of the present invention in cooperation with the liquid-cooling radiator to form the liquid-cooling heat dissipation system;

FIG. 10 is a perspective view of the liquid-cooling heat dissipation device according to a second embodiment of the present invention;

FIG. 11 is a cross-sectional view of the liquid-cooling heat dissipation device according to the second embodiment of the present invention;

FIG. 12 is an exploded of the liquid-cooling heat dissipation device according to the second embodiment of the present invention; and

FIG. 13 is a perspective view of the housing according to the second embodiment of the present invention.

### DETAILED DESCRIPTION OF THE PREFERRED EMBODIMENTS

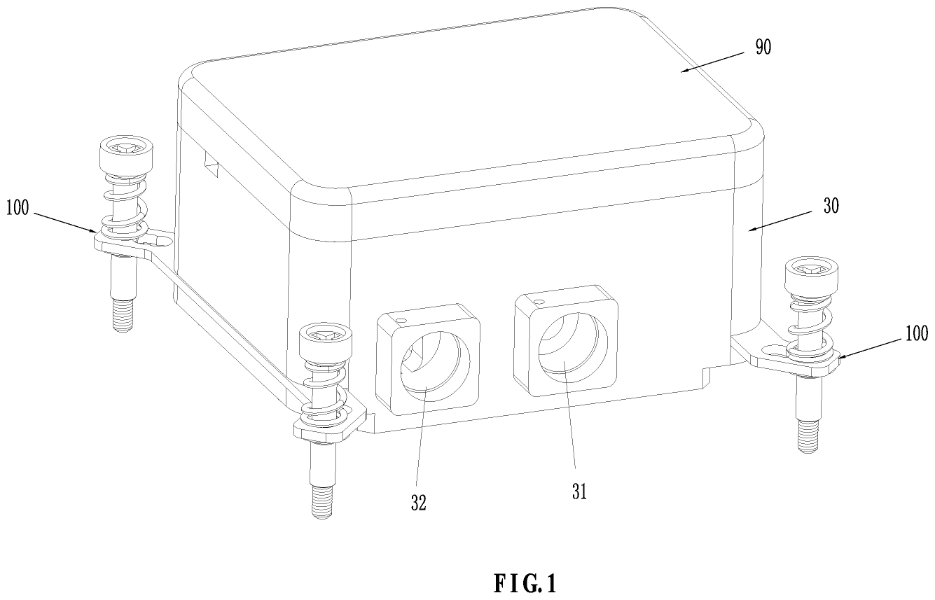

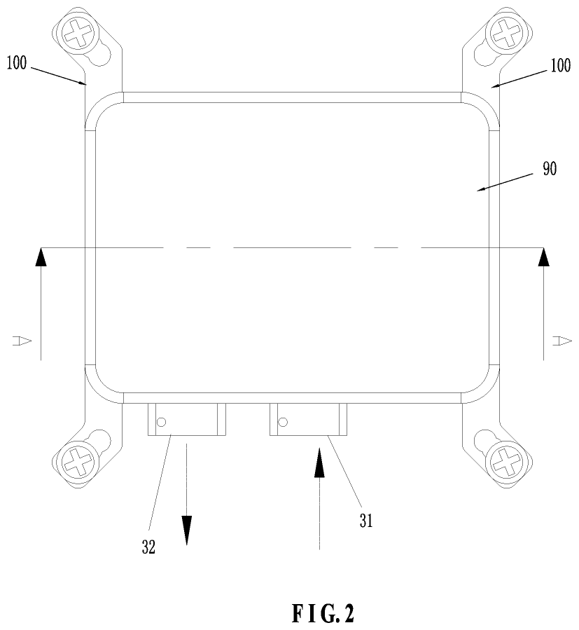

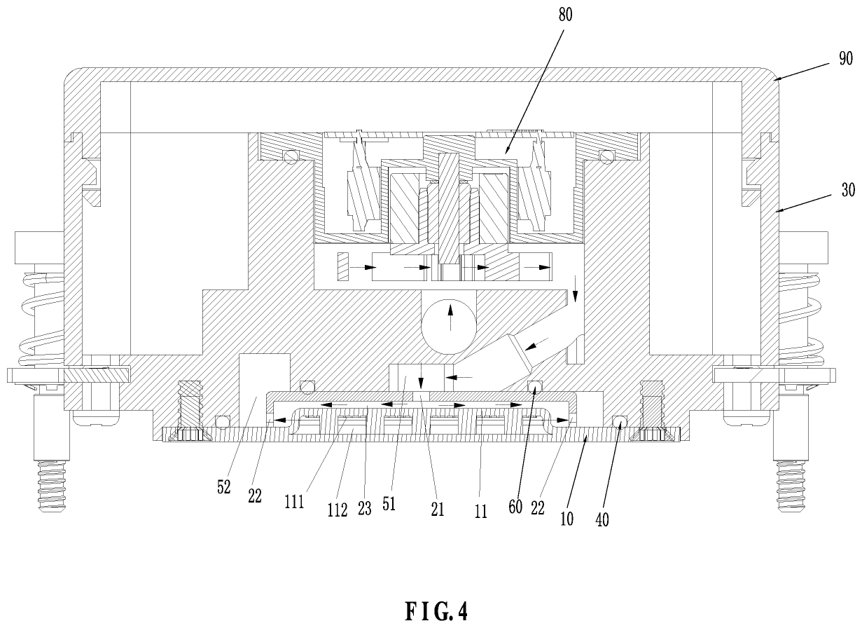

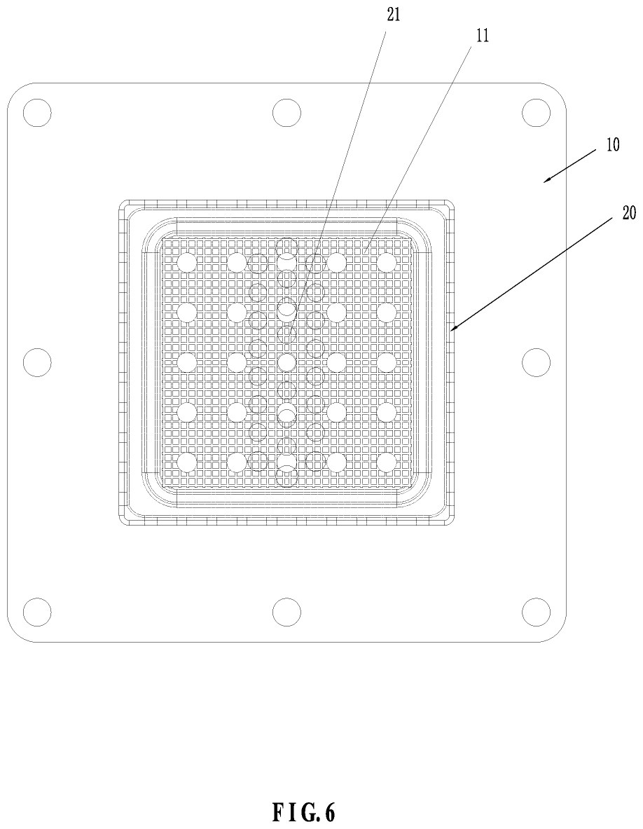

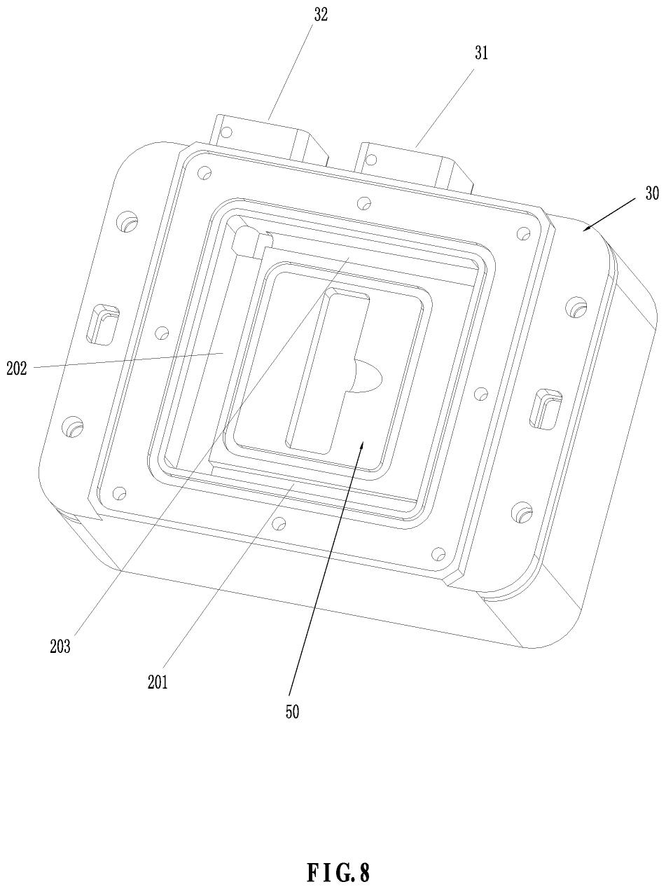

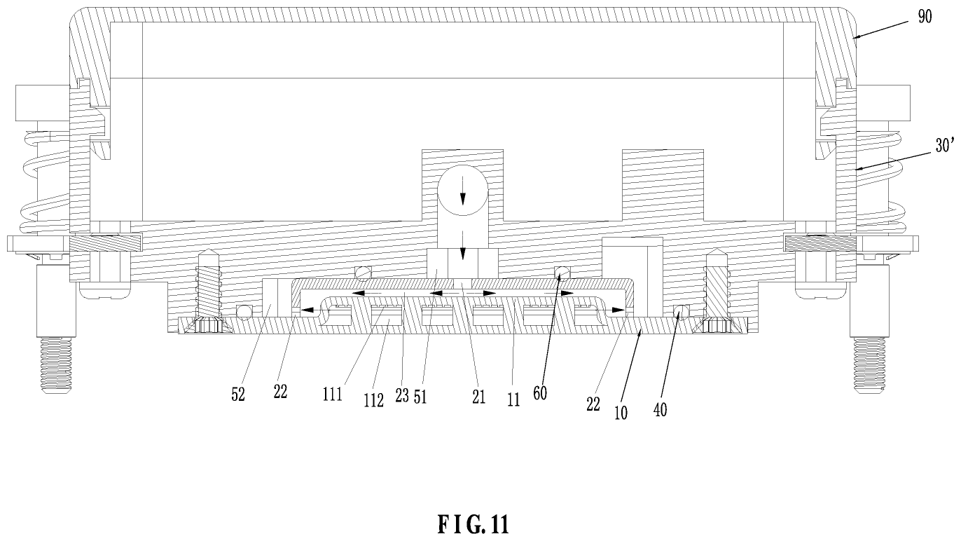

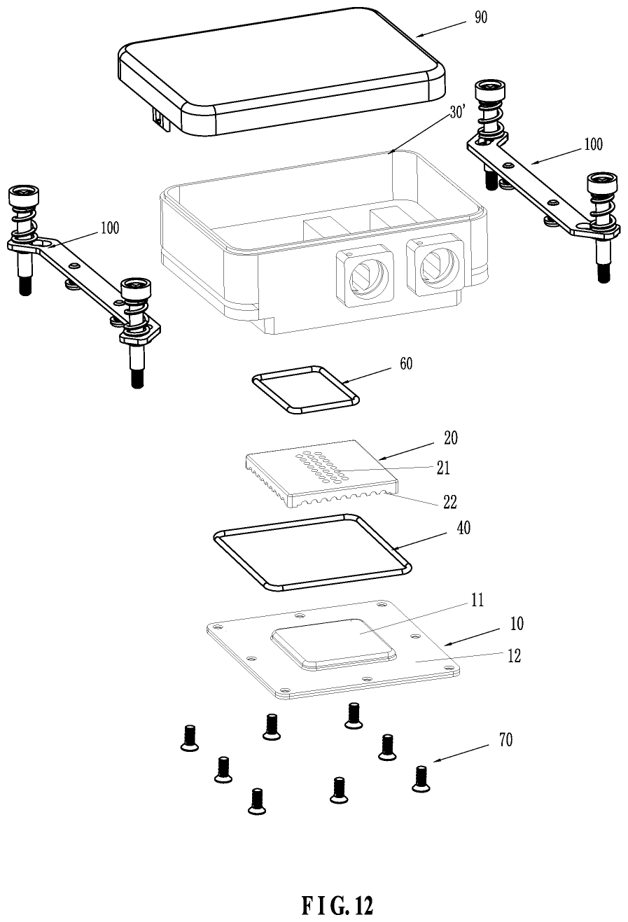

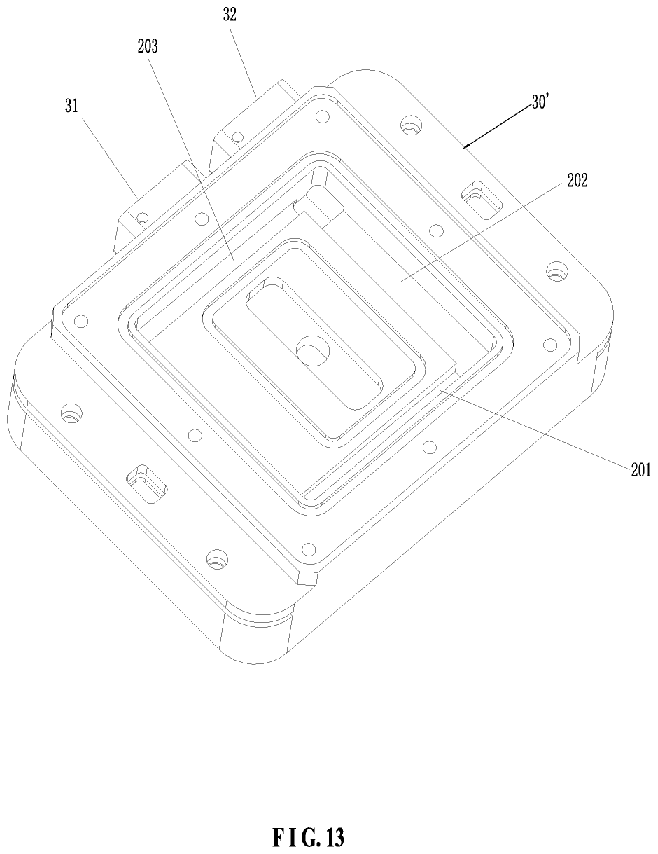

FIGS. 1 to 13 illustrate the specific structures of embodiments of the present invention.

First, referring to FIGS. 1 to 8, a liquid-cooling heat dissipation device for improving heat transfer efficiency, comprising a vapor chamber 10, a liquid-separating cover 20, and a housing 30.

The housing 30 has a cold liquid inlet 31 and a hot liquid outlet 32.

The vapor chamber 10 is mounted to the bottom of the housing 30. An accommodating cavity 50 is formed between the vapor chamber 10 and the housing 30. A first sealing ring 40 is sandwiched between the peripheral edge of the upper surface of the vapor chamber 10 and the housing 30.

The liquid-separating cover 20 covers the vapor chamber 10. The liquid-separating cover 20 separates the accommodating cavity 50 into a cold liquid cavity 51 and a hot liquid cavity 52. The cold liquid inlet 31 and the hot liquid outlet 32 communicate with the cold liquid cavity 51 and the hot liquid cavity 52, respectively. The top of the liquid-separating cover 20 is formed with a first perforation 21 communicating with the cold liquid cavity 51 and the interior 23 of the liquid-separating cover 20. The bottom of the peripheral side of the liquid-separating cover 20 is formed with a second perforation 22 communicating with the hot liquid cavity 52 and the interior 23 of the liquid-separating cover 20. A second sealing ring 60 is sandwiched between the peripheral edge of the upper surface of the liquid-separating cover 20 and the housing 30.

A cold liquid flows through the cold liquid inlet 31 into the cold liquid cavity 51, and then flows through the first perforation 21 into the exterior 23 of the liquid-separating cover 20. The cold liquid absorbs the heat of the vapor chamber 10 to become hot liquid. The hot liquid flows through the second perforation 22 at the bottom of the peripheral side of the liquid-separating cover 20 into the hot liquid cavity 52, and then flows out of the housing 30 via the hot liquid outlet 32.

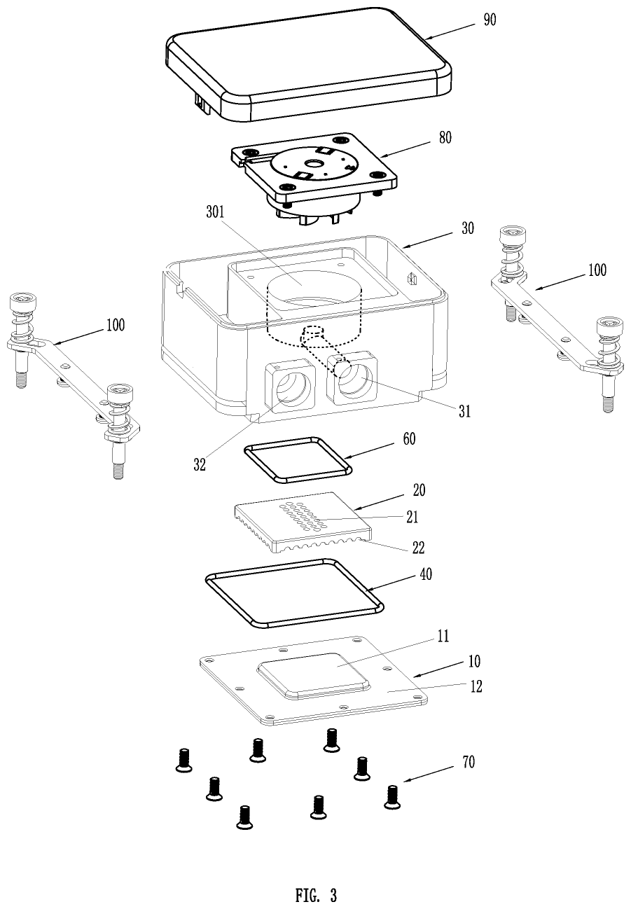

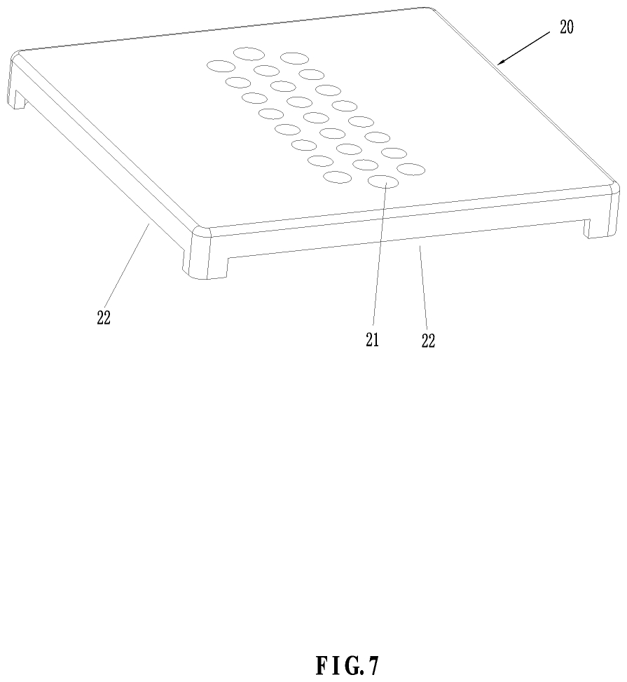

Preferably, the second perforation 22 is plural arranged around the liquid-separating cover 20 for the hot liquid to flow through the peripheral side of the liquid-separating cover 20. In actual design, the second perforation 22 is a plurality of densely distributed small holes or elongated holes extending along the periphery of the liquid-separating cover 20 (referring to FIG. 3 and FIG. 7).

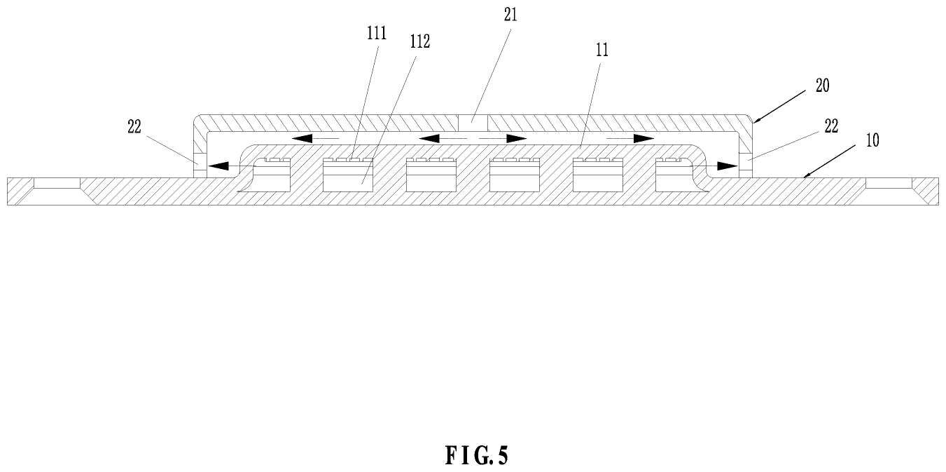

As shown in FIG. 3 and FIG. 5, the vapor chamber 10 has a protruding portion 11 extending upwardly. The protruding portion 11 has a vacuum cavity 112 therein. The inner wall of the vacuum cavity 112 has a capillary structure 111. The capillary structure 111 may refer to some convex and concave textures. The liquid-separating cover 20 covers the protruding portion 11. After the cold liquid flows into the interior 23 of the liquid-separating cover 20, the cold liquid absorbs the heat from the surface of the protruding portion 11 of the vapor chamber 10 to become the hot liquid. Preferably, the cold liquid cavity 51 is centrally arranged above the protruding portion 11 of the vapor chamber 10.

Generally, the bottom of the vapor chamber 10 is a flat surface. The vapor chamber 10 has an upper flat surface 12 located on the outer periphery of the protruding portion 11. The upper flat surface 12 is in sealing contact with the bottom of the housing 30 through the first sealing ring 40. The upper flat surface 12 is positioned relative to the bottom of the housing 30 and locked by a screw 70. The locking position of the screw 70 is at the outer periphery of the first sealing ring 40.

In this embodiment, a liquid pump cavity 301 is defined in the upper portion of the housing 30. An upper cover 90 is installed on the top of the housing 30 to seal the liquid pump cavity 301. A liquid pump 80 is provided in the liquid pump cavity 301. The bottom of the liquid pump cavity 301 has a through hole communicating with the cold liquid inlet 31 and the liquid pump cavity 301. The cold liquid is pumped upward from the through hole and flows into the liquid pump cavity 301. Through the action of the impeller of the liquid pump 80, the cold liquid flows out from the peripheral side of the liquid pump cavity 301 and then flows downward into the first perforation 21 of the liquid-separating cover 20. Generally, the cold liquid inlet 31 and the hot liquid outlet 32 are at the same liquid level.

The bottom of the housing 30 is formed with a strip-shaped groove corresponding to the hot liquid cavity 52. For example, a strip-shaped groove is arranged on each of the three sides of the liquid-separating cover 20, defined as a first strip-shaped groove 201, a second strip-shaped groove 202 and a third strip-shaped groove 203. The first strip-shaped groove 201 is connected to one end of the second strip-shaped groove 202 along the flow direction of the hot liquid. The other end of the second strip-shaped groove 202 and one end of the third strip-shaped groove 203 are interconnected and communicate with the hot liquid outlet 32. The inner top surfaces of the first strip-shaped groove 201, the second strip-shaped groove 202 and the third strip-shaped groove 203 are all gradually inclined along the flow direction of the hot liquid, such that the hot liquid in the hot liquid cavity 52 is guided through the first strip-shaped groove 201, the second strip-shaped groove 202 and the third strip-shaped groove 203. The hot liquid cavity 52 is gradually enlarged along the flow direction of the hot liquid, which is conducive to flow out the hot liquid.

Two sides of the bottom of the housing 30 are each provided with a foot stand assembly 100 to facilitate the installation and application of the entire liquid-cooling heat dissipation device.

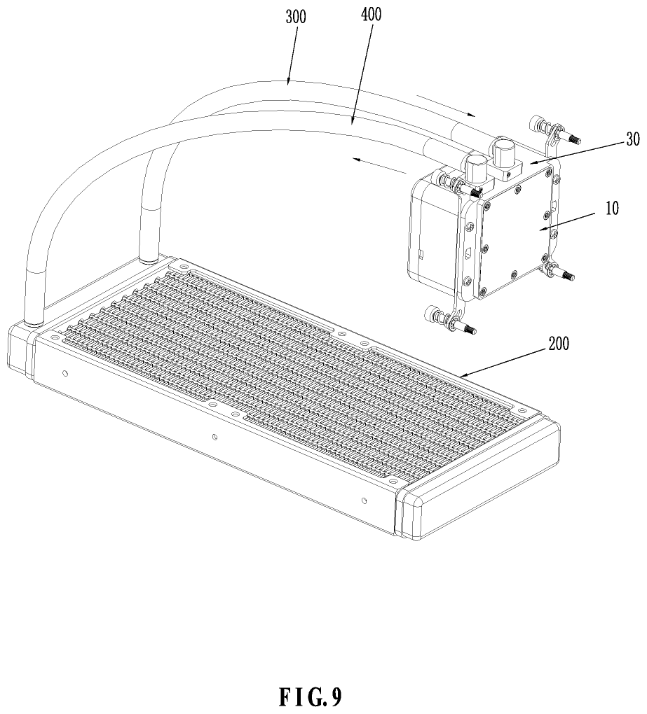

Referring to FIG. 9, a liquid-cooling heat dissipation system comprises a liquid-cooling radiator 200, a cold liquid input pipe 300 and a hot liquid output pipe 400 that are connected to the liquid-cooling radiator 200, and the above-mentioned liquid-cooling heat dissipation device. The cold liquid input pipe 300 is connected to the cold liquid inlet 31. The hot liquid output pipe 400 is connected to the hot liquid outlet 32.

The cold liquid in the cold liquid input pipe 300 flows into the housing 30 through the cold liquid inlet 31 and absorbs the heat of the vapor chamber 10 to become hot liquid. The hot liquid flows out of the housing 30 through the hot liquid outlet 32 and flows to the liquid-cooling radiator 200 through the hot liquid output pipe 400. The liquid-cooling radiator 200 dissipates the heat of the hot liquid to the outside to become cold liquid. The cold liquid flows into the cold liquid input pipe 300 again to be circulated. The liquid pump 80 is configured to supply circulation power.

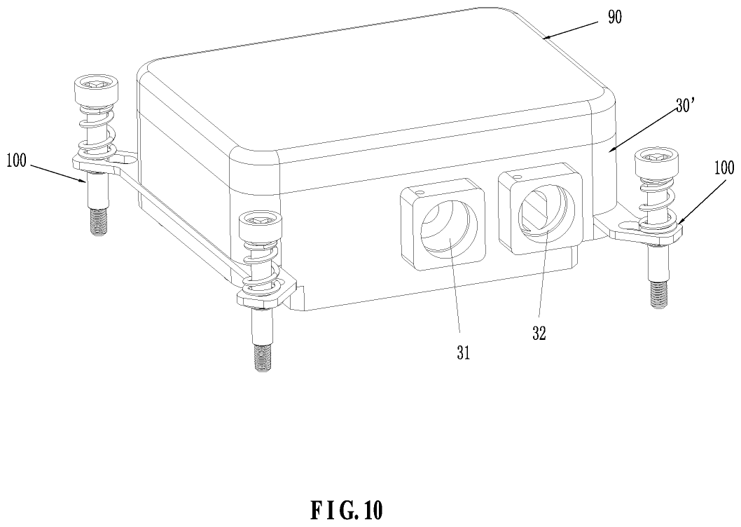

FIGS. 10 to 13 show the specific structure of a second embodiment. The main structure of the second embodiment is substantially similar to the first embodiment with the exceptions described hereinafter. In this embodiment, no liquid pump is provided in the housing 30′, so the structure of the housing 30′ is relatively simple. Similarly, the liquid-cooling heat dissipation device shown in FIG. 10 can cooperate with the liquid-cooling radiator, the cold liquid input pipe and the hot liquid output pipe to form a liquid-cooling heat dissipation system. It is only necessary to install a liquid pump outside the liquid-cooling heat dissipation device shown in FIG. 10. The installation position of the liquid pump can be selected flexibly without restriction.

What is claimed is:

1. A liquid-cooling heat dissipation device, comprising a vapor chamber, a liquid-separating cover, and a housing;
the housing having a cold liquid inlet and a hot liquid outlet; an accommodating cavity being formed between the vapor chamber and the housing, the liquid-separating cover covering the vapor chamber to separate the accommodating cavity into a cold liquid cavity and a hot liquid cavity, the cold liquid inlet and the hot liquid outlet communicating with the cold liquid cavity and the hot liquid cavity, respectively; a top of the liquid-separating cover being formed with a first perforation communicating with the cold liquid cavity and an interior of the liquid-separating cover, a bottom of a peripheral side of the liquid-separating cover being formed with a second perforation communicating with the hot liquid cavity and the interior of the liquid-separating cover;
a cold liquid flowing through the cold liquid inlet into the cold liquid cavity and then flowing through the first perforation into the exterior of the liquid-separating cover, the cold liquid absorbing heat of the vapor chamber to become hot liquid, the hot liquid flowing through the second perforation into the hot liquid cavity and then flowing out of the housing via the hot liquid outlet.

2. The liquid-cooling heat dissipation device as claimed in claim 1, wherein the second perforation is plural arranged around the liquid-separating cover.

3. The liquid-cooling heat dissipation device as claimed in claim 1, wherein the vapor chamber has a protruding portion extending upwardly, the protruding portion has a vacuum cavity therein, an inner wall of the vacuum cavity has a capillary structure; the liquid-separating cover convers the protruding portion, after the cold liquid flows into the interior of the liquid-separating cover, the cold liquid absorbs heat from a surface of the protruding portion of the vapor chamber to become the hot liquid.

4. The liquid-cooling heat dissipation device as claimed in claim 3, wherein the vapor chamber has an upper flat surface located on an outer periphery of the protruding portion, the upper flat surface is in sealing contact with a bottom of the housing through a first sealing ring, the upper flat surface is positioned relative to the bottom of the housing and locked by a screw, and a locking position of the screw is at an outer periphery of the first sealing ring.

5. The liquid-cooling heat dissipation device as claimed in claim 1, wherein a liquid pump cavity is defined in an upper portion of the housing, a liquid pump is provided in the liquid pump cavity; the cold liquid flows through the cold liquid inlet into the liquid pump cavity, through action of an impeller of the liquid pump, the cold liquid flows out from a peripheral side of the liquid pump cavity and then flows downward into the first perforation of the liquid-separating cover.

6. The liquid-cooling heat dissipation device as claimed in claim 3, wherein the cold liquid cavity is centrally arranged above the protruding portion of the vapor chamber.

7. A liquid-cooling heat dissipation system, comprising a liquid-cooling radiator, a cold liquid input pipe and a hot liquid output pipe that are connected to the liquid-cooling radiator, and the liquid-cooling heat dissipation device as claimed in claim 1; the cold liquid input pipe being connected to the cold liquid inlet, the hot liquid output pipe being connected to the hot liquid outlet; the cold liquid in the cold liquid input pipe flowing into the housing through the cold liquid inlet and absorbing heat of the vapor chamber to become hot liquid, the hot liquid flowing out of the housing via the hot liquid outlet and flowing to the liquid-cooling radiator through the hot liquid output pipe, the liquid-cooling radiator dissipating heat of the hot liquid to become cold liquid, the cold liquid flowing into the cold liquid input pipe again to be circulated, the liquid pump being configured to supply circulation power.
